(19) United States
(12) Patent Application Publication
(10) Pub. No.: US 2018/0039176 A1
(43) Pub. Date: Feb. 8, 2018

(54) COLORED RESIN COMPOSITION, COLORED FILM, DECORATIVE SUBSTRATE AND TOUCH PANEL

(71) Applicant: TORAY INDUSTRIES, INC., Tokyo (JP)

(72) Inventors: Yoshihiko Inoue, Otsu-shi (JP); Ryosuke Aihara, Otsu-shi (JP)

(73) Assignee: TORAY INDUSTRIES, INC., Tokyo (JP)

(21) Appl. No.: 15/715,985

(22) Filed: Sep. 26, 2017

Related U.S. Application Data
(63) Continuation of application No. PCT/JP2016/059409, filed on Mar. 24, 2016.

(30) Foreign Application Priority Data
Mar. 30, 2015 (JP) 2015-068208

(51) Int. Cl. G03F 7/038; G03F 7/00; G03F 7/004; G03F 7/16; G03F 7/20; H01L 27/32; G03F 7/40; G03F 7/037; G03F 7/028; H01L 51/00; G06F 3/044; C08G 73/10; G03F 7/32

(52) U.S. Cl. CPC G03F 7/0387; C08G 73/1082; C08G 73/106; C08G 73/1042; C08G 73/1039; C08G 73/1053; C08G 73/1046; G03F 7/0007; G03F 7/0046; G03F 7/0048; G03F 7/162; G03F 7/168; G03F 7/2004; G03F 7/322; G03F 7/40; G03F 7/037; G03F 7/028; H01L 51/0035; G06F 3/044; H01L 27/3272; H01L 27/3258; H01L 51/5284

(57) ABSTRACT

A colored resin composition is disclosed including a polyimide resin having a specified structure to achieve remarkable heat resistance and enabling the formation of a colored film which is excellent in reliability because a coloring material is highly dispersed and stabilized therein. A colored resin composition is disclosed including (A) an alkali-soluble polyimide resin having a structural unit containing a phenolic hydroxyl group, a sulfonic acid group or a thiol group, (B) a coloring material, (C) a polymeric dispersant, and (D) an organic solvent. A patterned colored layer obtained from the composition of the present invention is useful for a decorative substrate, a touch panel, an organic EL display device and the like.

### CROSS REFERENCE TO RELATED APPLICATIONS

This is Continuation application of PCT/JP2016/059409, filed Mar. 24, 2016, which claims priority to Japanese Patent Application No. 2015-068203, filed Mar. 30, 2015, the disclosures of these applications being incorporated herein by reference in their entireties for all purposes.

### TECHNICAL FIELD OF THE INVENTION

The present invention relates to a colored resin composition, a colored film, a decorative substrate and a touch panel.

### BACKGROUND OF THE INVENTION

In recent years, mobile equipment prepared with a projected capacitive type touch panel such as a smartphone and a tablet PC has been rapidly prevailing. It is common that a pattern of an ITO (Indium Tin Oxide) films is formed in a screen area of the projected capacitive type touch panel, and furthermore, a metal wiring section made of molybdenum and the like is formed at a peripheral part thereof. And then, in order to conceal such a metal wiring section, there are many cases in which a black-, white- or the like colored light-shielding pattern is formed inside a sheet of cover glass of the projected capacitive type touch panel.

Touch panel systems are roughly classified into an Out-cell type in which a touch panel layer is formed between a sheet of cover glass and a liquid crystal panel, an On-cell type in which a touch panel layer is formed on a liquid crystal panel, an In-cell type in which a touch panel layer is formed in the inside of a liquid crystal panel, and an OGS (One Glass Solution) type in which a touch panel layer is directly formed on a sheet of cover glass. OGS type touch panels are being actively developed since the OGS type can attain reduced thickness and reduced weight as compared with the Out-cell type which is a conventional type (Patent Document 1).

In the OGS type touch panel, a light-Shielding pattern is required to have a high heat resistance because an ITO electrode and the like are formed under a high temperature after the light-shielding pattern is formed on a sheet of cover glass, and furthermore, the light-shielding pattern has also been required to have a chemical resistance in a patterning process for the ITO electrode.

Although some techniques for forming a black-colored light-shielding pattern excellent in heat resistance and chemical resistance by photolithography using a photosensitive resin composition containing a cardo resin have been known (Patent Documents 2 and 3), the light-shielding pattern has been required to have a further improved heat resistance and the like. On the ether hand, in order to obtain a light-shielding pattern further excellent in heat resistance and chemical resistance, a composition prepared by dispersing a coloring material in a polyimide resin has also been attempted to be obtained (Patent Documents 4 and 5).

### PATENT DOCUMENTS

Patent Document 1: Japanese Patent Laid-open Publication No. 2009-301767

Patent Document 2: Japanese Patent Laid-open Publication No. 2012-145699

Patent Document 3: Japanese Patent Laid-open Publication No. 2014-099159

Patent Document 4: Japanese Patent Laid-open Publication No. 2005-162905

Patent Document 5: Japanese Patent Laid-open Publication No. 2009-051891

### SUMMARY OF THE INVENTION

However, organic solvents capable of dissolving a polyimide resin are limited to high-polarity solvents such as N-methylpyrrolidone and γ-butyrolactone. In such a high-polarity solvent, a coloring material, particularly an organic pigment or carbon black, which is subjected to a surface treatment or covered with a resin, is extremely difficult to be dispersed and stabilized, and there has been a problem, that color characteristics and insulation properties of the light-shielding pattern formed fail to be controlled.

On that account, an embodiment of the present invention is aimed at providing a colored resin composition including a polyimide resin having a specified structure to achieve remarkable heat resistance and enabling the formation of a colored film which is excellent in reliability because a coloring material is highly dispersed and stabilized therein.

As a result of extensive researches, the present inventors have found that a colored resin composition in which a coloring material is dispersed in a mixture of a polyimide resin having a specified structure, a polymeric dispersant and an organic solvent may be extremely effective in solving the above-mentioned problems, and have completed the present invention.

That is, an embodiment of the present invention has the following configuration.

(1) There is provided a colored resin composition including (A) an alkali-soluble polyimide resin having a structural unit represented by the following general formula (1), (B) a coloring material, (C) a polymeric dispersant, and (D) an organic solvent.

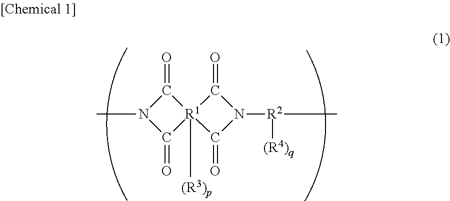

(In the general formula (1), R¹ represents a 4- to 10-valent organic group, R² represents a 2- to 8-valent organic group, R³ and R⁴ independently represent a phenolic hydroxyl group, a sulfonic acid group, a thiol group or a carboxyl group, p and q independently represent an integer of 0 to 6, and the sum of p and q is set to 1 or more.).

Moreover, in the present invention, there are preferred embodiments described below.

(2) The colored resin composition described in (1), wherein the (C) polymeric dispersant has no acid value and has an amine value.

(3) The colored resin composition described in (1) or (2), wherein the (C) polymeric dispersant has a tertiary amino group or a nitrogen-containing heterocyclic basic functional group.

(4) The colored resin composition described in any one of (i) to (3), wherein the (D) organic solvent is composed mainly of an acetate-based solvent.

(5) The colored resin composition described in any one of (1) to (4), wherein the (B) coloring material is composed of an organic pigment and/or an inorganic pigment.

Moreover, as a colored film, there is an embodiment described below.

(6) A colored film being composed of a cured product of the colored resin composition described in any one of those mentioned above.

And then, as those which utilize the merit of the colored film, there are embodiments described below.

(7) A decorative substrate being provided with the colored film mentioned above.

(8) A touch panel being provided with the decorative substrate mentioned above.

(9) An organic EL display device having the colored film mentioned above on at least one layer of a flattening layer on a driving circuit and an insulating layer on a first electrode.

According to the colored resin composition of the present invention, it becomes possible to form a colored film which is enhanced in reliability because a coloring material is highly dispersed and stabilized therein and is provided with remarkable heat resistance.

### DETAILED DESCRIPTION OF EMBODIMENTS OF THE INVENTION

The colored resin composition according to an embodiment of the present invention is characterized as including (A) an alkali-soluble polyimide resin having a specified structural unit, (B) a coloring material, (C) a polymeric dispersant, and (D) an organic solvent.

The colored resin composition according to an embodiment of the present invention includes (A) an alkali-soluble polyimide resin having a structural unit represented by the following general formula (1).

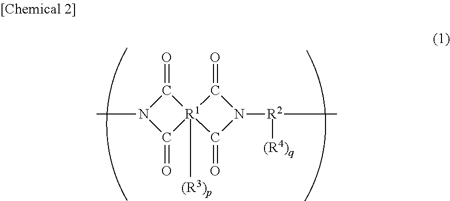

(In the general formula (1), R¹ represents a 4- to 10-valent organic group, R² represents a 2- to 8-valent organic group, R³ and R⁴ independently represent a phenolic hydroxyl group, a sulfonic acid group or a thiol group, and p and q independently represent an integer of 0 to 6.)

As the alkali-soluble polyimide resin, a resin dissolving in an inorganic alkali such as potassium hydroxide and in an organic alkali such as tetramethylammonium hydroxide (TMAH) within a prescribed time is preferred, specifically, a resin dissolving within 2 minutes when the resin is immersed at 23° C. in a sufficient amount of a 0.05% aqueous KOH solution or a sufficient amount of a 2.38% aqueous TMAH solution is generally preferred.

In this connection, the alkali-soluble polyimide resin used in the present invention does not need to be completely imidized, and for example, an alkali-soluble polyimide resin with non-imidized moieties accounting for 10% or less of the whole moiety to be imidized is also included therein.

In the general formula (1), R²-(R³)ₚ represents the residue left after an acid dianhydride which is a raw material is imidized. R¹ is a 4- to 10-valent organic group, and then, it is preferred that R¹-(R³)ₚ, is an organic group with 5 to 40 carbon atoms having an aromatic ring or a cycloaliphatic group.

As the acid dianhydride, ones described below and other ones in which 1 to 6 hydrogen atoms in the aromatic ring or cycloaliphatic group thereof are substituted with R³s are exemplified.

Examples thereof include aromatic tetracarboxylic acid dianhydrides such as pyromellitic acid dianhydride, 3,3′,4,4′-biphenyltetracarboxylic acid dianhydride, 3,3′,4,4′-benzophenonetetracarboxylic acid dianhydride, bis(3,4-dicarboxyphenyl)sulfone dianhydride, bis(3,4-dicarboxyphenyl)ether dianhydride and 2,2-bis(3,4-dicarboxyphenyl)hexafluoropropane dianhydride; and aliphatic tetracarboxylic acid dianhydrides such as butane tetracarboxylic acid dianhydride, 1,2,3,4-cyclopentane tetracarboxylic acid dianhydride, bicyclo[2.2.2]oct-7-ene-tetracarboxylic acid dianhydride and bicyclo[2.2.2]octane tetracarboxylic acid dianhydride.

For enhancing the storage stability of the colored resin composition, bis(3,4-dicarboxyphenyl)ether dianhydride, 2,2-bis(3,4-dicarboxyphenyl)hexafluoropropane dianhydride, bicyclo[2.2.2]oct-7-ene-tetracarboxylic acid dianhydride, bicyclo[2.2.2]octane tetracarboxylic acid dianhydride, an acid dianhydride represented by the general formula (2) and ones in which some or all of hydrogen atoms thereof are substituted with R³s are preferred.

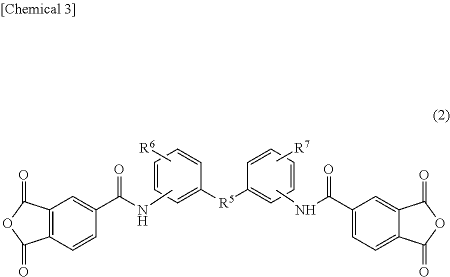

(In the general formula (2), R⁵ represents a single bond, an oxygen atom, a sulfur atom, CH₂, C(CF₃)₂, C(CH₃)₂, SO₂ or diphenylcyclopentane, and R⁶ and R⁷ independently represent a hydrogen atom, a hydroxyl group or a thiol group.)

Considering from a different point of view, it is preferred that R¹ is a functional group making benzene, biphenyl, a diphenylalkane, benzophenone, diphenyl sulfone, diphenyl ether, a cycloalkane with 5 to 8 carbon atoms or a structure obtained by removing the acid anhydride group from a compound represented by the general formula (2) its skeleton. Moreover, in the case where this functional group has a plurality of benzene rings, it is preferred that two acid anhydride groups are bonded to different benzene rings respectively.

In the general formula (1), R²-(R⁴)_{q} represents the residue left after a diamine is subjected to an imidization reaction, R² is a 2- to 8-valent organic group, and then, it is preferred that R²-(R⁴)_{q} is an organic group with 5 to 40 carbon atoms having an aromatic ring or a cycloaliphatic group.

Examples of the diamine include m-phenylenediamine, p-phenylenediamine, 1,4-bis(4-aminophenoxy)benzene, 1,3-bis(4-aminophenoxy)benzene, 1,3-bis(3-aminophenoxy)benzene, bis[4-(4-aminophenoxy)phenyl]sulfone, bis[4-(4-aminophenoxy)phenyl]propane, bis[4-(4-aminophenoxy)phenyl]hexafluoropropane, bis[4-(3-aminophenoxy)phenyl]sulfone, 9,9-bis(4-aminophenyl)fluorene, 2,5-bis(aminomethyl)bicyclo[2.2.1]heptane, 2,6-bis(aminomethyl)bicyclo[2.2.1]heptane, diaminodiphenyl ether, diaminodiphenyl sulfone, diaminodiphenyl methane, diaminodiphenyl propane, diaminodiphenyl hexafluoropropane, diaminodiphenyl thioether, benzidine, 2,2′-bistrifluorobenzidine, diamines represented by the following general formula (3) or (4), and substituted diamines derived therefrom.

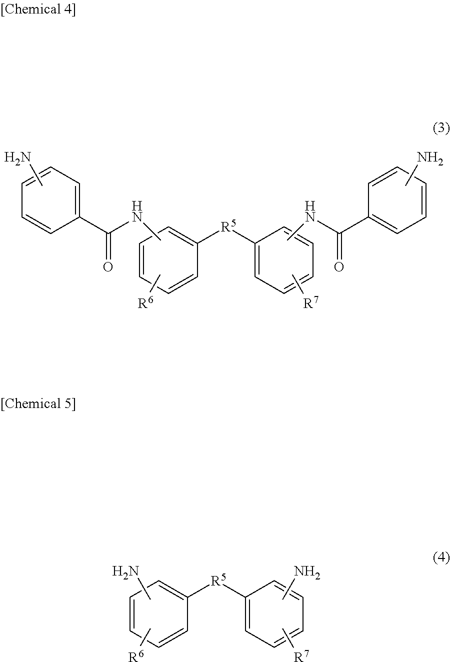

(In the general formulas (3) and (4), R⁵ represents a single bond, an oxygen atom, a sulfur atom, CH₂, C(CF₃)₂, C(CH₃)₂, SO₂ or diphenylcyclopentane, and R⁶ and R⁷ independently represent a hydrogen atom, a hydroxyl group or a thiol group.)

Considering from a different point of view, it is preferred that R² is a functional group making benzene, biphenyl, fluorene, a diphenylalkane, benzophenone, diphenyl sulfone, diphenyl ether, diphenyl thioether, a cycloalkane with 5 to 8 carbon atoms or a compound obtained by removing the amino group from the compound represented by the general formula (3) or (4) its skeleton. Moreover, in the case where this functional group has a plurality of benzene rings, it is preferred that two amino groups are bonded to different benzene rings respectively.

It is preferred that the alkali-soluble polyimide resin having a structural unit represented by the general formula (1) have an active hydrogen-containing polar group selected from the group consisting of a carboxyl group, a phenolic hydroxyl group, a sulfonic acid group and a thiol group at the main-chain terminal. The introduction of these active hydrogen-containing polar groups into the main-chain terminal can be achieved by using a terminal blocking agent having an active hydrogen-containing polar group. Examples of such a terminal blocking agent include a monoamine, an acid anhydride, a monocarboxylic acid, a monoacid chloride compound, and a monovalent active ester compound.

The monoamine used as the terminal blocking agent is exemplified below.

Examples thereof include 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol and 4-aminothiophenol.

Each of the acid anhydride, the monocarboxylic acid, the monoacid chloride compound and the monovalent active ester compound which are used as the terminal blocking agent is exemplified below.

Examples of the acid anhydride include acid anhydrides such as phthalic anhydride, maleic anhydride, nadic acid, cyclohexanedicarboxylic acid anhydride and 3-hydroxyphthalic acid anhydride.

Examples of the monocarboxylic acid include 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxynaphthalene, 3-carboxybenzenesulfonic acid, 4-carboxybenzenesulfonic acid, and the like.

Examples of the monoacid chloride compound include a compound in which a carboxyl group of the above-mentioned monocarboxylic acid is made into an acid chloride.

Examples of the monoacid chloride compound include a compound in which only one carboxyl group of a kind of dicarboxylic acid such as terephthalic acid, phthalic acid, maleic acid, cyclohexanedicarboxylic acid, 1,5-di carboxynaphthalene, 1,6-dicarboxynaphthalene, 1,7-dicarboxynaphthalene and 2,6-dicarboxynaphthalene is made into an acid chloride.

Examples of the active ester compound include a compound obtained by a reaction between the above-mentioned monoacid chloride compound and N-hydroxybenzotriazole or N-hydroxy-5-norbornene-2, 3-dicarboxamide.

The proportion of the monoamine used as the terminal blocking agent is preferably 0.1 to 60% by mole and more preferably 1 to 40% by mole relative to the whole amine component. The proportion of the acid anhydride, the monocarboxylic acid, the monoacid chloride compound or the monovalent active ester compound which is used as the terminal blocking agent is preferably 0.1 to 100% by mole and more preferably 5 to 90% by mole relative to the diamine component.

Furthermore, in order to enhance the adhesion between a colored film prepared by curing the colored resin composition of the present invention and a substrate and the like, R² or R⁵ may be substituted by an aliphatic substituent having a siloxane structure within the range of not lowering the heat resistance. Examples of such an alkali-soluble polyimide resin include an alkali-soluble polyimide resin containing bis(3-aminopropyl)tetramethyldisiloxane or bis(p-amino-phenyl)octamethylpentasiloxane as a diamine component in an amount of 1 to 10% by mole.

With regard to the colored resin composition of the present invention, another alkali-soluble resin other than the alkali-soluble polyimide resin represented by the general formula (1) may be added thereto. Although no particular restriction is put on another alkali-soluble resin, examples thereof include a polyimide resin, an acrylic resin, a siloxane resin, a cardo resin, and the like. Although the proportion occupied by the alkali-soluble polyimide resin represented by the general formula (1) in the alkali-soluble resin needs only to be appropriately decided by desired heat resistance, dispersion stability and the like, the proportion is preferably 10% by mass or more and more preferably 50% by mass or more.

The production method of an alkali-soluble polyimide resin is exemplified by the following method.

First, for example, a process of obtaining a polyimide precursor by the following method is exemplified.

(a) A method of making a tetracarboxylic acid dianhydride and a diamine compound (monoamine compound-components are substituted for some components thereof) undergo a reaction under a low temperature.

(b) A method of making a tetracarboxylic acid dianhydride (acid anhydride-, monoacid chloride compound- or monovalent active ester compound-components are substituted for some components thereof) and a diamine compound undergo a reaction under a low temperature.

(c) A method of making a tetracarboxylic acid dianhydride and a kind of alcohol undergo a reaction to obtain a diester compound, and afterward, making the diester compound and a diamine (monoamine compound-components are substituted for some components thereof) undergo a reaction in the presence of a condensation agent.

(d) A method of making a tetracarboxylic acid dianhydride and a kind of alcohol undergo a reaction to obtain a diester, afterward, making a dicarboxylic acid left in the reactant into an acid chloride, and then, making the product and a diamine compound (Monoamine compound-components are substituted for some components thereof.) undergo a reaction. Furthermore, a process of obtaining a polyimide resin by the following method is exemplified.

(a) A method of completely imidizing the obtained polyimide precursor by a known method.

(b) A method of leaving a non-imidized structure by stopping an imidization reaction during the course of the reaction in which the polyimide precursor obtained is further imidized.

(c) A method of partially introducing an imide structure by mixing a completely imidized polyimide resin therewith.

Alternatively, a method of making a tetracarboxylic acid dianhydride and a diisocyanate compound undergo a reaction at a high temperature to produce a polyimide by a decarboxylation reaction may be utilized.

For enhancing the chemical resistance of s colored film prepared by curing the colored resin composition according to an embodiment of the present invention and the solubility to an alkali developing solution, the weight average molecular weight of the alkali-soluble polyimide resin is preferably 5000 to 100000 and more preferably 10000 to 70000.

The colored resin composition according to an embodiment of the present invention includes (B) a coloring material. The (B) coloring material refers to an organic pigment, an inorganic pigment or a dye which is generally used also in a field of electronic information materials. In order to enhance the heat resistance of a colored film prepared by curing the colored resin composition of the present invention and the reliability thereof, the organic pigment or the inorganic pigment is preferred.

The organic pigment is exemplified below.

Examples thereof include a diketopyrrolopyrrole-based pigment, azo-based pigments such as azo, disazo and polyazo; phthalocyanine-based pigments such as copper phthalocyanine, halogenated copper phthalocyanine and metal-free phthalocyanine; anthraquinone-based pigments such as aminoanthraquinone, diamino dianthraquinone, anthrapyrimidine, flavanthrone, anthanthrone, indanthrone, pyranthrone and violanthrone; and other than these, a quinacridone-based pigment, a dioxazine-based pigment, a perinone-based pigment, a perylene-based pigment, a thioindigo-based pigment, an isoindoline-based pigment, an isoindolinone-based pigment, a quinophthalone-based pigment, a thren-based pigment and a metal complex-based pigment.

The inorganic pigment is exemplified below.

Examples thereof include titanium oxide, zinc flower, zinc sulfide, white lead, calcium carbonate, precipitated barium sulfate, white carbon, alumina white, kaolin clay, talc, bentonite, black iron oxide, cadmium red, red iron oxide, molybdenum red, molybdate orange, chrome vermilion, chrome yellow, cadmium yellow, yellow iron oxide, titanium yellow, chromium oxide, viridian, titanium cobalt green, cobalt green, cobalt chromium green, Victoria green, ultramarine blue, Prussian blue, cobalt blue, cerulean blue, cobalt silica blue, cobalt zinc silica blue, manganese violet and cobalt violet.

As the dye, an azo dye, an anthraquinone dye, a condensed polycyclic aromatic carbonyl dye, an indigoid eye, a carbonium dye, a phthalocyanine dye, a methine dye and a polymethine dye are exemplified.

Examples of a red pigment include Pigment Red 9, 48, 97, 122, 123, 144, 149, 166, 168, 177, 179, 180, 192, 209, 215, 216, 217, 220, 223, 224, 226, 227, 228, 240 or 254 (any of these numbers refers to Color Index (hereinafter, “CI” number)).

Examples of an orange pigment include Pigment Orange 13, 36, 38, 43, 51, 55, 59, 61, 64, 65 or 71.

Examples of a yellow pigment include Pigment Yellow 12, 13, 17, 20, 24, 83, 86, 93, 95, 109, 110, 117, 125, 129, 137, 138, 139, 147, 148, 150, 153, 154, 166, 168 or 185 (any of these numbers refers to the CI number)).

Examples of a violet pigment include Pigment Violet 19, 23, 29, 30, 32, 37, 40 or 50 (any of these numbers refers to the CI number)).

Examples of a blue pigment include Pigment Blue 15, 15:3, 15:4, 15:6, 22, 60 or 64 (any of these numbers refers to the CI number)).

Examples of a green pigment include Pigment Green 7, 10, 36 or 58 (any of these numbers refers to the CI number)).

Examples of a black pigment include a black organic pigment, a color-mixed organic pigment, an inorganic pigment or the like. Examples of the black organic pigment include carbon black, perylene black, aniline black and a benzofuranone-based pigment. Examples of the color-mixed organic pigment include a pigment made to turn pseudo black by mixing two or more kinds of pigments having a red, blue, green, violet, yellow, magenta or cyan color.

The inorganic pigment is exemplified, below.

Examples thereof include graphite; fine particles of a metal such as titanium, copper, iron, manganese, cobalt, chromium, nickel, zinc, calcium or silver; an oxide of the metal, a composite oxide of metals mentioned above, a sulfide of the metal, a nitride of the metal and an oxynitride of the metal. Of these, carbon black and a titanium nitride, which have a high light shielding property, are preferred.

Examples of a white pigment include titanium dioxide, barium carbonate, zirconium oxide, calcium carbonate, barium sulfate, alumina white and silicon dioxide.

The dye is exemplified below.

Examples thereof include Direct Red 2, 4, 9, 23, 26, 28, 31, 39, 62, 63, 72, 75, 76, 79, 80, 81, 83, 84, 89, 92, 95, 111, 173, 164, 207, 211, 212, 214, 218, 221, 223, 224, 225, 226, 227, 232, 233, 240, 241, 242, 243 or 247; Acid Red 35, 42, 51, 52, 57, 62, 80, 82, 111, 114, 118, 119, 127, 128, 131, 143, 145, 151, 154, 157, 158, 211, 249, 254, 257, 261, 263, 266, 289, 299, 301, 305, 319, 336, 337, 361, 396 or 397; Reactive Red 3, 13, 17, 19, 21, 22, 23, 24, 29, 35, 37, 40, 41, 43, 45, 49 or 55; Basic Red 12, 13, 14, 15, 18, 22, 23, 24, 25, 27, 29, 35, 36, 38, 39, 45 or 46; Direct Violet 7, 9, 47, 48, 51, 66, 90, 93, 94, 95, 96, 100 or 101; Acid Violet 5, 9, 11, 34, 43, 47, 48, 51, 75, 90, 103 or 126; Reactive Violet 1, 3, 4, 5, 6, 7, 8, 9, 16, 17, 22, 23, 24, 26, 27, 33 or 34; Basic Violet 1, 2, 3, 7, 10, 15, 16, 20, 21, 25, 27, 28, 35, 37, 39, 40 or 48; Direct Yellow 8, 9, 11, 12, 27, 28, 29, 33, 35, 39, 41, 44, 50, 53, 58, 59, 68, 87, 93, 95, 96, 98, 100, 106, 108, 109, 110, 130, 142, 144, 161 or 163; Acid Yellow 17, 19, 23, 25, 39, 40, 42, 44, 49, 50, 61, 64, 76, 79, 110, 127, 135, 143, 151, 159, 169, 174, 190, 195, 196, 197, 199, 218, 219, 222 or 227; Reactive Yellow 2, 3, 13, 14, 15, 17, 18, 23, 24, 25, 26, 27, 29, 35, 37, 41 or 42; Basic Yellow 1, 2, 4, 11, 13, 14, 15, 19, 21, 23, 24, 25, 28, 29, 32, 36, 39 or 40; Acid Green 16; Acid Blue 9, 45, 80, 83, 90 or 185; and Basic Orange 21 or 23 (any of these numbers refers to the CI number)).

It is preferred that the mass ratio of the coloring material/the resin component included in the coloring material resin composition of the present invention be 90/10 to 20/80, and it is more preferred that the mass ratio thereof be 90/10 to 40/60. In this context, the resin component refers to the resin component constituted of an alkali-soluble polyimide resin, additives such as a polymeric dispersant and a polymeric compound further added in some cases which are combined together. When the amount of the resin component is too small, there are cases where the dispersion stability of the coloring material becomes insufficient. On the other hand, when the amount of the coloring material is too small, there are cases where the coloration of a colored film prepared by curing the colored resin composition of the present invention becomes insufficient.

The colored resin composition according to an embodiment of the present invention includes (C) a polymeric dispersant. By making the colored resin composition include the (C) polymeric dispersant, the coloring material can be uniformly and stably dispersed in the resin composition. Examples of the (C) polymeric dispersant include a polyester-based polymeric dispersant, an acryl-based polymeric dispersant, a polyurethane-based polymeric dispersant, a polyallylamine-based polymeric dispersant and a carbodiimide-based dispersant.

As the polymeric dispersant, a polymer having a main chain constituted of polyamine, polyether, polyester, polyurethane, poly(meth)acrylate or the like and a functional group with a polarity which is selected from an amine, a carboxylic acid, a phosphoric acid, an amine salt, a carboxylate, a phosphate or the like as a side chain is preferred. It is considered that the polar functional group as a side chain thereof is adsorbed to the pigment, the contact between two different coloring agents is hindered because the main chain of the polymer has a steric hindrance effect, and as a result, the dispersion of the coloring agents is stabilized.

Examples of a polymer having a polar functional group include a polymer having only an amine value, a polymer having only an acid value, a polymer having an amine value and an acid value, and a polymer having neither an amine value nor an acid value. As the polymeric dispersant of the present invention, a dispersant having an amine value is preferred. It does not matter if the polymeric dispersant has an acid value, but the polymeric dispersant is preferably a dispersant having no acid value and having only an amine value. In this connection, the amine value of the polymeric dispersant is preferably 10 mgKOH/g or more and 100 mgKOH/g or less, and is more preferably 10 mgKOH/g or more and 60 mgKOH/g or less. There is a tendency that the dispersion-stabilizing effect is hardly obtained in the case where the amine value is low, and there is a tendency that the solubility to an alkali developing solution of a photosensitive resin composition is lowered and the pattern processability deteriorates in the case where the amine value is high.

Specific examples of a dispersant having only an amine value are exemplified below.

Examples thereof include “DISPERBYK” (trade name) 102, 160, 161, 162, 2163, 164, 2164, 166, 167, 168, 2000, 2050, 2150, 2155, 9075 or 9077; BYK-LP N6919, BYK-LP N21116 and BYK-LP N21234 (hereinabove, any of these is available from BYK Japan KK); “EFKA” (trade name) 4015, 4020, 4046, 4047, 4050, 4055, 4060, 4080, 4300, 4330, 4340, 4400, 4401, 4402, 4403 or 4800 (hereinabove, any of these is available from BASF Japan Ltd.); “AJISPER” (registered trademark) PB711 (available from Ajinomoto Fine-Techno Co., Inc.); and “SOLSPERSE” (registered trademark) 13240, 13940, 20000, 71000 or 76500 (hereinabove, any of these is available from The Lubrizol corporation).

Even among the dispersants having only an amine value, a dispersant having a tertiary amino group or a basic functional group including a nitrogen-containing heterocycle and the like such as pyridine, pyrimidine, pyrazine and isocyanurate is preferred. The polymeric dispersant having a tertiary amino group or a nitrogen-containing heterocyclic basic functional group is exemplified below.

Examples thereof include “DISPERBYK” 164, 167, BYK-LP N6919; BYK-LP N21116; and “SOLSPERSE” 20000.

Examples of the polymeric dispersant having an amine value and an acid value include “DISPERBYK” (trade name) 142, 145, 2001, 2010, 2020, 2025 or 9076, Anti-Terra-205 (hereinabove, any of these is available from BYK Japan KK), “SOLSPERSE” (registered trademark) 24000 (available from The Lubrizol Corporation), “AJISPER” (registered trademark) PB821, PB880 or PB881 (hereinabove, any of these is available from Ajinomoto Fine-Techno Co., Inc.) and “SOLSPERSE” (registered trademark) 9000, 11200, 13650, 24000SC, 24000GR, 32000, 32500, 32550, 326000, 33000, 34750, 35100, 35200, 37500, 35000 or 56000 (available from The Lubrizol Corporation).

For enhancing the dispersion stability while maintaining the heat resistance, it is preferred that the amount of the polymeric dispersant is a smaller ratio within the possible range for the proportion occupied thereby in the resin component, and specifically, relative to the whole amount of the resin component, the amount thereof is preferably 1 to 50% by mass and more preferably 1 to 30% by mass. On the other hand, relative to the whole amount of the coloring material, the amount thereof is preferably 1 to 100% by mass and more preferably 3 to 30% by mass. Moreover, the weight average molecular weight of the polymeric dispersant is preferably 1000 or mere and 100000 or less and more preferably 3000 or more and 50000 or less. In the case where the molecular weight is low, a sufficient dispersion-stabilizing effect is not obtained, and in the case where the molecular weight is high, there occurs a problem that the solubility to an alkali developing solution is lowered.

The colored resin composition according to an embodiment of the present invention includes (D) an organic solvent. Examples of the (D) organic solvent include a compound of a kind of ether, a kind of acetate, a kind of ester, a kind of ketone, a kind of aromatic hydrocarbon, a kind of amide, and a kind of alcohol.

More specifically, the following are exemplified.

Examples thereof include a kind of ether such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, dipropylene glycol dimethyl ether, dipropylene glycol methyl-n-butyl ether, tripropylene glycol monomethyl ether, tripropylene glycol monoethyl ether, diethylene glycol dimethyl ether, diethylene glycol methyl ethyl ether, diethylene glycol diethyl ether and tetrahydrofuran.

The following ester compounds can also be used.

Examples thereof include acetates such as butyl acetate, ethylene glycol monomethyl ether acetate, ethylene glycol monoethyl ether acetate, propylene glycol monomethyl ether acetate, 3-methoxy butyl acetate, ethylene glycol monobutyl ether acetate, diethylene glycol monomethyl ether acetate, diethylene glycol monoethyl ether acetate, diethylene glycol monobutyl ether acetate, cyclohexanol acetate, propylene glycol diacetate, propylene glycol monomethyl ether acetate, propylene glycol monoethyl ether acetate (hereinafter, “PGMEA”), dipropylene glycol methyl ether acetate, 3-methoxy-3-methyl-1-butyl acetate, 1,4-butanediol diacetate, 1,3-butylene glycol diacetate and 1,6-hexanediol diacetate; a kind of ketone such as methyl ethyl ketone, cyclohexanone, 2-heptanone and 3-heptanone; a kind of alkyl lactate such as methyl 2-hydroxypropionate and ethyl 2-hydroxypropionate; ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, ethyl 2-oxobutanoate, and the like.

Other than these, the following solvents can also be used.

Examples thereof include a kind of aromatic hydrocarbon such as toluene and xylene; a kind of amide such as N-methylpyrrolidone, N,N-dimethylformamide and N,N-dimethylacetamide; and a kind of alcohol such as butyl alcohol, isobutyl alcohol, pentanol, 4-methyl-2-pentanol, 3-methyl-2-butanol, 3-methyl-3-methoxybutanol and diacetone alcohol.

In this connection, in order to make the interaction between the polymeric dispersant and the pigment more effective, it is preferred that the solubility parameter: SP value of an organic solvent is made to lie within an appropriate range. The SP value is preferably 7.5 or more and 10.0 or less, a solvent with an SP value of 8.5 or more and 10.0 or less is preferred, and it is preferred that such a solvent in an amount of 50% by mass or more is contained in the solvent and it is further preferred that ouch a solvent in an amount of 70% by mass or more is contained therein. In the case where the SP value is low, the polymeric dispersant and the alkali-soluble resin are hardly dissolved and become difficult to be dispersed therein, and in the case where the SP value is high, there is a tendency that the dispersion-stabilizing effect by the polymeric dispersant becomes small.

Of these, for further dispersing and stabilizing the coloring material, it is preferred that a kind of acetate is used. Specifically, the proportion occupied by the compound of a kind of acetate in the whole (D) organic solvent which the colored resin composition of the present invention includes is preferably 50 to 100% by mass and more preferably 70 to 100% by mass.

With upsizing in a substrate on which a colored film is formed, the coating application by a die coating apparatus has been becoming the mainstream, in order to realize suitable volatility and dryability in this coating method, the (D) organic solvent including two or more kinds of compounds mixed is preferred. For making the film thickness of a coating film of the colored resin composition of the present invention uniform and improving the smoothness and stickiness of the surface thereof, the proportion of an organic solvent with a boiling point of 150 to 200° C. is preferably 30 to 75% by mass relative to the whole (D) organic solvent.

The proportion of the (D) organic solvent to the whole solid content of the colored resin composition of the present invention is preferably 20 to 800 parts by pass and more preferably 30 to 500 parts by mass relative to 100 parts by mass of the whole solid content.

By making the colored resin composition according to an embodiment of the present invention include (E) a photopolymerizable compound and (F) a photopolymerization initiator, the colored resin composition is imparted with photosensitivity.

Examples of the (E) photopolymerizable compound include a monomer and an oligomer having a polyfunctional group or a monofunctional group. In this context, the functional group refers to the polymerizable group, and the double bond of carbon-carbon is suitable therefor.

Polyfunctional group monomers and polyfunctional group oligomers are exemplified below.

Examples of a (meth) acrylic acid-based compound include bisphenol A diglycidyl ether (meth)acrylate, poly(meth)acrylate carbamate, modified bisphenol A epoxy (meth)acrylate, adipic acid 1,6-hexanediol (meth) acrylic acid ester, phthalic anhydride propylene oxide (meth)acrylic acid ester, trimellitic acid diethylene glycol (meth)acrylic acid ester, rosin-modified epoxy di (meth)acrylate, alkyd-modified (meth)acrylate, a fluorene diacrylate-based oligomer, tripropylene glycol di(meth)acrylate, 1,6-hexanediol di(meth)acrylate, bisphenol A diglycidyl ether di(meth)acrylate, trimethylol propane tri (meth)acrylate, pentaerythritol tri(meth)acrylate, triacrylformal, pentaerythritol tetra(meth)acrylate or an acid-modified product thereof, dipentaerythritol hexa(meth)acrylate or an acid-modified product thereof, dipentaerythritol penta(meth)acrylate or an acid-modified product thereof, 2,2-bis[4-(3-acryloxy-2-hydroxypropoxy)phenyl]propane, bis[4-(3-acryloxy-2-hydroxypropoxy)phenyl]methane, bis[4-(3-acryloxy-2-hydroxypropoxy)phenyl]sulfone, bis[4-(3-acryloxy-2-hydroxypropoxy)phenyl]ether, 4,4′-bis[4-(3-acryloxy-2-hydroxypropoxy)phenyl]cyclohexane, 9,9-bis[4-(3-acryloxy-2-hydroxypropoxy)phenyl]fluorene, 9,9-bis[3-methyl-4-(3-acryloxy-2-hydroxypropoxy)phenyl]fluorene, 9,9-bis[3-chloro-4-(3-acryloxy-2-hydroxypropoxy)phenyl]fluorene, bisphenoxyethanol fluorene diacrylate, bisphenoxyethanol fluorene dimethacrylate, biscresol fluorene diacrylate or biscresol fluorene dimethacrylate, and a polycondensate of dipentaerythritol penta(meth)acrylate and dipentaerythritol hexa(meth)acrylate.

By appropriately selecting and combining these polyfunctional group monomers, monofunctional group monomers and oligomers, characteristics such as sensitivity and processability of the resulting photosensitive colored resin composition can be adjusted. Of these, in order to enhance the sensitivity, a compound having three or more polymerizable groups is preferred, and furthermore, a compound having five or more polymerizable groups is more preferred. Further preferred are dipentaerythritol hexa(meth)acrylate or an acid-modified product thereof, and dipentaerythritol penta(meth)acrylate or an acid-modified product thereof. Moreover, for enhancing the developability and processability, an unsaturated group-containing alkali-soluble monomer obtained by making a reactant between an epoxy compound having two glycidyl ether groups and methacrylic acid react with a polybasic acid carboxylic acid or an acid anhydride thereof is also preferred. Furthermore, for controlling the pattern shape at the time of development, using a (meth)acrylate having a fluorene ring which contains a plurality of aromatic rings in its molecule and is highly contributing to water repellency together therewith is also useful.

The amount of the photopolymerizable compound is preferably 1 to 70% by mass and more preferably 20 to 50% by mass relative to the whole amount of the resin component. In the case where the addition amount is small, it is not preferred because sufficient photosensitive characteristics are not obtained and processing becomes difficult, and in the case where the addition amount is large, it is not preferred because the shrinkage on curing of a film formed becomes large and the lowering in adhesion to a base material is caused and wrinkles are generated in the film due to film stress.

As (F) a photo-radical polymerization initiator, an alkylphenone-based photopolymerization initiator or an oxime ester-based photopolymerization initiator is preferred.

Examples of the alkylphenone-based photopolymerization initiator include an α-aminoalkylphenone-based photopolymerization initiator and an α-hydroxyalkylphenone-based photopolymerization initiator. For further heightening the sensitivity, the α-aminoalkylphenone-based photopolymerization initiator is preferred. Examples of the α-aminoalkylphenone-based photopolymerization initiator include 2,2-diethoxyacetophenone, 2-methyl-1-(4-methylthiophenyl)-2-morpholinopropane-1-one, 2-benzyl-2-dimethylamino-1-(4-morpholinophenyl)-butanone referred to as “IRGACURE” (registered trademark) 369 and 2-(dimethylamino)-2-[(4-methylphenyl)methyl]-1-[4-(morpholinyl)phenyl]-1-butanone referred to as “IRGACURE” (registered trademark) 379, 1-hydroxycyclohexyl phenyl ketone (hereinabove, any of these is available from BASF Japan Ltd.): and 2-hydroxy-2-methyl-1-phenylpropane-1-one.

Examples of the oxime ester-based photopolymerization initiator include 1,2-octanedione, 1-[4-(phenylthio)-2-(o-benzoyloxime)] referred to as “IRGACURE” (registered trademark) OXE01 and ethanone, 1-[9-ethyl-6-(2-methylbenzoyl)-9H-carbazole-3-yl]-, 1-(o-acetyloxime) referred to as “IRGACURE” (registered trademark) OXE02; and “ADEKA” (registered trademark) OPTOMER N-1818, N-1919 and “ADEKA ARKLS” NCI-831 (hereinabove, any of these is available from ADEKA CORPORATION).

In addition to these photopolymerization initiators, a benzophenone-based compound, an oxanthone-based compound, an imidazole-based compound, a benzothiazole-based compound, a benzoxazole-based compound, a carbazole-based compound, a triazine-based compound and a phosphorus-based compound, and an inorganic system photopolymerization initiator such as a titanate may be combinedly used. Such photopolymerization initiators are exemplified below.

Examples thereof include benzophenone, N,N′-tetraethyl-4,4′-diaminobenzophenone, 4-methoxy-4′-dimethylaminobenzophenone, benzoin, benzoin methylether, benzoin isobutylether, benzyl dimethyl ketal, α-hydroxyisobutylphenone, thioxanthone, 2-chlorothioxanthone, t-butylanthraquinone, 1-chloroanthraquinone, 2,3-dichloroanthraquinone, 3-chloro-2-methylanthraquinone, 2-ethylanthraquinone, 1,4-naphthoquinone, 9,10-phenanthraquinone, 1,2-benzoanthraquinone, 1,4-dimethylanthraquinone, 2-phenylanthraquinone, 2-(o-chlorophenyl) -4,5-diphenylimidazole dimer, 2-mercaptobenzothiazole, 2-mercaptobenzoxazole and 4-(p-methoxyphenyl)-2,6-di-(trichloromethyl)-s-triazine.

The amount of the photopolymerization initiator is preferably 0.1 to 40% by mass relative to the whole amount of the resin component, and in the case where two or more kinds of photopolymerization initiators are mixed to be used, the amount thereof is preferably 0.2 to 60% by mass in total.

For enhancing the reliability of a colored film prepared by curing the colored resin composition of the present invention and the chemical resistance thereof, it is preferred that the colored resin composition of the present invention include a thermally crosslinkable compound. Thermally crosslinkable compounds having one thermally crosslinkable group are exemplified below.

Examples thereof include ML-26X, ML-24X, ML-236TMP, 4-methylol 3M6C, ML-MC or ML-TBC (hereinabove, any of these is available from Honshu Chemical industry Co., Ltd.) and P-a type benzoxazine (available from SHIKOKU CHEMICALS CORPORATION).

Thermally crosslinkable compounds having two thermally crosslinkable groups are exemplified below.

Examples thereof include DM-BI25X-F, 46DMOC, 46DMOIPP or 46DMOEP (hereinabove, any of these is available from ASAHI YUKIZAI CORPORATION); DML-MBPC, DML-MBOC, DML-OCHP, DML-PC, DML-PCHP, DML-PTBP, DML-34X, DML-EP, DML-POP, DML-OC, Dimethylol-Bis-C, Dimethylol-BisOC-P, DML-BisOC-Z, DML-BisOCHP-Z, DML-PFP, DML-PSBP, DML-MB25, DML-MTrisPC, DML-Bis25X-34XL or DML-Bis25X-PCHP (hereinabove, any of these is available from Honshu Chemical Industry Co., Ltd.); NIKALAC MX-290 (available from SANWA CHEMICAL CO., LTD.); B-a type benzoxazine or B-m type benzoxazine (hereinabove, any of these is available from SHIKOKU CHEMICALS CORPORATION); 2,6-dimethoxymethyl-4-t-butylphenol, 2,6-dimethoxymethyl-p-cresol and 2,6-diacetoxymethyl-p-cresol.

Thermally crosslinkable compounds having three thermally crosslinkable groups are exemplified below.

Examples thereof include TriML-P, TriML-35XL and TriML-TrisCR-HAP (hereinabove, any of these is available from Honshu Chemical Industry Co., Ltd.).

Thermally crosslinkable compounds having four thermally crosslinkable groups are exemplified below.

Examples thereof include TM-BIP-A (available from ASAHI YUKIZAI CORPORATION); TML-BP, TML-HQ, TML-pp-BPF, TML-BPA or TMOM-BP (hereinabove, any of these is available from Honshu Chemical Industry Co., Ltd.); and “NIKALAC” MX-280 or “NIKALAC” MX-270 (hereinabove, any of these is available from SANWA CHEMICAL CO., LTD.).

Thermally crosslinkable compounds having six thermally crosslinkable groups are exemplified below.

Examples thereof include HML-TPPHBA or HML-TPHAP (hereinabove, any of these is available from Honshu Chemical Industry Co., Ltd.); and “NIKALAC” MW-390 or “NIKALAC” KW-100LM (hereinabove, any of these is available from SANWA CHEMICAL CO., LTD.).

Of these, compounds having two or more thermally crosslinkable groups are preferred, and “NIKALAC” MX-280 or “NIKALAC” MX-270 which is an alicyclic-based compound, B-a type benzoxazine or B-m type benzoxazine, and “NIKALAC” MW-390 or “NIKALAC” MW-100LM which has six thermally crosslinkable groups are preferred.

The colored resin composition of the present invention can include a compound having a phenolic hydroxyl group for controlling the alkali developability thereof. In this connection, this so-called compound having a phenolic hydroxyl group is distinguished from a polyamide represented by the general formula (1).

The compound having a phenolic hydroxyl group is exemplified below.

Examples thereof include Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCR-IPZ, BisOCP-IPZ, BisOIPP-CP, Bis26X-IPZ, BisOTBP-CP, TekP-4HBPA (tetrakis P-DO-BPA), TrisP-HAP, TrisP-PA, BisOFP-Z, BisRS-2P, BisPG-26X, BisRS-3P, BisOC-OCHP, BisPC-OCHP, Bis25X-OCHP, Bis26X-OCHP, BisOCHP-OC, Bis236T-OCHP, Methylenetris-FR-CR, BisRS-26X or BisRS-OCHP (hereinabove, any of these is available from Honshu Chemical Industry Co., Ltd.); and BIR-OC, BIP-PC, BIR-PC, BIR-PTBP, BIR-PCHP, BIP-BIOC-F, 4PC, BIR-BIPC-F or TEP-BIP-A (hereinabove, any of these is available from ASAHI YUKIZAI CORPORATION).

Of these, Bis-Z, BisP-EZ, TekP-4HBPA, TrisP-HAP, TrisP-PA, BisOCHP-Z, BisP-MZ, BisP-PZ, BisP-IPZ, BisOCP-IPZ, BisP-CP, BisRS-2P, BisRS-3P, BisP-OCHP, Methylenetris-FR-CR, BisRS-26X, BIP-PC, BIR-PC, BIR-PTBP or BIR-BIPC-F is preferred. Furthermore, Bis-Z, TekP-4HBPA, TrisP-HAP, TrisP-PA, BisRS-2P, BisRS-3P, BIR-PC, BIR-PTBP or BIR-BIPC-F is preferred.

The proportion of the compound having a phenolic hydroxyl group to the resin component is preferably 1 to 60 parts by mass and more preferably 3 to 50 parts by mass relative to 100 parts by mass of the resin component.

For enhancing the adhesion between a colored film prepared by curing the colored resin composition of the present invention and a substrate, the colored resin composition of the present invention may include an adhesion improving agent. As the adhesion improving agent, a silane coupling agent is preferred. As the silane coupling agent, a silane coupling agent in which a hydrolyzable group such as a hydrocarbon group, which has a functional group including a vinyl group, an epoxy group, a styryl group, a methacryloxy group, an acryloxy group or an amino group, and an alkoxyl group is bonded to the silicon atom is exemplified. Examples thereof include 3-glycidoxypropyltrimethoxysilane, 3-glycidoxypropyltriethoxysilane, 3-glycidoxypropylmethyldimethoxysilane, 3-glycidoxypropylmethyldiethoxysilane, 2-(3,4-epoxycyclohexyl)ethyltrimethoxysilane, 3-chloropropylmethyldimethoxysilane, 3-chloropropyltrimethoxysilane, vinyltrimethoxysilane, vinyltriethoxysilane, vinyltris(2-methoxyethoxy)silane, N-(2-aminoethyl) -3-aminopropylmethyldimethoxysilane, N-(2-aminoethyl)-3-aminopropyltrimethoxysilane, 3-methacryloxypropyltrimethoxysilane, 3-acryloxypropyltrimethoxysilane, 3-aminopropyltrimethoxysilane, 3-aminopropyltriethoxysilane, 3-triethoxysilyl-N-(1,3-dimethyl-butylidene)propylamine, 3-mercaptopropyltrimethoxysilane, 3-ureidopropyltriethoxysilane, 3-isocyanatepropyltriethoxysilane and p-styryltrimethoxysilane.

The colored resin composition of the present invention may include a surfactant in order to enhance the coating properties thereof and the smoothness of a coating film surface and to prevent a Benard cell. The proportion of the surfactant to the pigment is preferably 0.001 to 10% by mass and more preferably 0.01 to 1% by mass. The surfactant is exemplified below.

Examples thereof include anionic surfactants such as laurylsurfate ammonium and polyoxyethylenealkylether surfate triethanolamine; cationic surfactants such as stearylamine acetate and lauryltrimethylammonium chloride; ampholytic surfactants such as lauryldimethylamine oxide and laurylcarboxymethylhydroxyethylimidazolium betaine, nonionic surfactants such as polyoxyethylene lauryl ether, polyoxyethylene stearyl ether and sorbitan monostearate, silicone-based surfactants having a main skeleton including polydimethylsiloxane and the like, and fluorine-based surfactants.

Examples of a production method of the coloring material resin composition of the present invention include a method of dispersing a coloring material in a solution of an alkali-soluble polyimide resin using a dispersing machine.

Examples of the dispersing machine include a ball mill, a bead mill, a sand grinder, a three roll mill and a high-speed impact mill. For improving the dispersion efficiency and attaining the fine dispersion, a bead mill is preferred. Examples of the bead mill include the CoBall Mill, a basket mill, a pin mill and the DYNO-MILL. Examples of beads for the bead mill include titania beads, zirconia beads and zircon beads. The diameter of the bead for the bead mill is preferably 0.01 to 5.0 mm and more preferably 0.03 to 1.0 mm. In the case where the primary particle diameter of the coloring material and the particle diameter of the secondary particle formed of agglomerated primary particles are small, minute beads with a diameter of 0.03 to 0.10 mm are preferred. In this case, a bead mill equipped with a centrifugal separation type separator capable of separating minute beads and a dispersion is preferred. On the other hand, in the case where a coloring material containing coarse particles with a diameter of submicron order is dispersed, beads with a diameter of 0.10 mm or more are preferred because sufficient crushing power is attained.

Next, with regard to a method of curing the colored resin composition of the present invention and forming a film resistant to coloration, a negative-type photosensitive colored resin composition will be given as an example to be explained.

A photosensitive colored resin composition is applied on a substrate to obtain a coating film. Examples of the substrate include a transparent substrate made of soda glass, alkali-free glass, quartz glass or the like, a silicon wafer, a substrate made of a kind of ceramic, and a gallium arsenide substrate. Examples of a method of applying the colored resin composition include spin coating with a spinner, spray coating die coating, and roll coating. Although the film thickness of a coating film needs only to be appropriately decided by the coating method and the like, it is general to make the film thickness after drying within the range of 1 to 150 μm.

The coating film obtained is dried to obtain a dried film. It is general to perform drying for 1 minute to several hours (for example 5 hours) at 50 to 150° C. by heating and drying with an oven or a hot plate, air drying, drying under reduced pressure infrared-ray irradiation, or the like.

The dried film obtained is irradiated with actinic rays through a mask having a desired pattern to be subjected to exposure, and an exposed film is obtained. Examples of the actinic rays irradiated thereto include ultraviolet rays, visible light rays, electron rays and X rays. It is preferred that i-line (365 nm), h-line (405 nm) or g-line (436 nm) emitted from a mercury lamp be irradiated to the colored resin composition of the present invention.

The exposed film obtained is subjected to development with an alkaline developing solution and the like, and unexposed portions are removed to obtain a pattern. As the alkaline developing solution, an aqueous solution of an alkaline compound exemplified below can be used.

Examples thereof include a kind of inorganic alkali such as sodium hydroxide, potassium hydroxide, sodium carbonate, potassium carbonate, sodium silicate, sodium metasilicate, and aqueous ammonia; primary amines such as ethylamine and n-propylamine; secondary amines such as diethylamine and di-n-propylamine; tertiary amines such as triethylamine and methyldiethylamine; a kind of tetraalkylammonium hydroxide such as tetramethylammonium hydroxide (TMAH); quaternary ammonium salts such as choline; a kind of alcoholamine such as triethanolamine, diethanolamine, monoethanolamine, dimethylaminoethanol and diethylaminoethanol; and a kind of cyclic amine such as pyrrole, piperidine, 1,8-diazabicyclo[5,4,0]-7-undecene, 1,5-diazabicyclo[4,3,0]-5-nonane and morpholine.

Although it is general to make the concentration of an alkaline compound in the alkaline developing solution lie within the range of 0.01 to 50% by mass, the concentration thereof is preferably 0.02 to 10% by mass and more preferably 0.02 to 1% by mass. Moreover, for further improving the pattern shape after development, a surfactant such as a nonionic surfactant in an amount of 0.1 to 5% by mass may be added thereto. Furthermore, in the case where the developing solution is an alkali aqueous solution, a water-soluble organic solvent such as ethanol, γ-butyrolactone, dimethylformamide or N-methyl-2-pyrrolidone maybe added to the developing solution.

Examples of a method for the development include an immersion method, a spraying method and a paddle method. The pattern obtained may be subjected to rinse-washing by means of pure water and the like.

The pattern obtained can be subjected to a heating treatment (post-baking) to obtain a colored film patterned. It is general to perform this heating treatment continuously or gradually for 0.25 to 5 hours at 150 to 300° C. under an air or nitrogen atmosphere or under vacuum.

A colored resin composition including a black coloring material among colored resin compositions of the present invention can be suitably utilized for the formation of a light-shielding image constituting a black matrix or the like of a color filter with which a liquid crystal display device or the like is equipped, a colored partition wall in the inside of an organic EL display, or a colored film constituting a decorative substrate with which a touch panel is equipped.

Furthermore, since a cured film prepared by curing the colored resin composition of embodiments of the present invention has a high heat resistance, the film can be suitably used as a flattening layer or an insulating layer of a display device having a substrate on which a TFT is formed, a flattening layer on a driving circuit, an insulating layer on a first electrode and a display element, in this order. Examples of the display device with such a constitution include a liquid crystal display device, an organic EL display device and the like, and the cured film can be more suitably used in the organic EL display device in which a cured film is required to have a higher heat resistance and a lower outgassing property as compared with the flattening layer or the insulating layer.

### EXAMPLES

Hereinafter, the present invention will be described in detail with reference to examples and comparative examples, but the present invention is not limited thereto.

### Synthesis Example 1

### Synthesis of Polyimide Resin (P-1)

Under a stream of dry nitrogen, 30.03 g of 2,2-bis (3-amino-4-hydroxyphenyl)hexafluoropropane (0.082 mol), 1.24 g of 1,3-bis(3-aminopropyl)tetramethyldisiloxane (0.005 mol) and 2.73 g of 3-aminophenol (0.025 mol) which is a terminal blocking agent were dissolved in 100 g of N-methyl-2-pyrrolidone (hereinafter, “NMP”). To this, 31.02 g of bis(3,4-dicarboxyphenyl)ether dianhydride (0.10 mol) and 30 g of NMP were added and stirred for 1 hour at 20° C., and furthermore, the contents were stirred for 4 hours at 180° C. while removing water. After the completion of the reaction, the reaction liquid was charged into 2 L of water, and the precipitate produced was collected by filtration to be washed three times with water. The precipitate was dried for 20 hours by means of a vacuum drying machine at 80° C. to obtain a polyimide resin (P-1).

### Synthesis Example 2

### Synthesis of Polyimide Precursor (P-2)

With 2082.6 g of γ-butyrolactone and 2082.6 g of NMP, 138.2 g of 4,4′-diaminophenyl ether (0.30 mol), 161.7 g of paraphenylenediamine (0.65 mol) and 28.6 g of bis (3-aminopropyl) tetramethyldisiloxane (0.05 mol) were mixed. To this, 711.7 g of 3,3′,4,4′-oxydiphthalic carboxylic dianhydride (0.9975 mol) was added, and the contents were stirred for 3 hours at 80° C. To this, 1.1 g of maleic anhydride (0.02 mol) was added, and furthermore, the contents were stirred for 1 hour at 80° C. to obtain a polyimide precursor (P-2) solution with a solid content of 20% by mass.

### Synthesis Example 3

### Synthesis of Acrylic Resin (P-3)

A copolymer of methylmethacrylate/methacrylic acid/styrene (mass ratio 30/40/30) was synthesized. One hundred parts by mass of the copolymer was subjected to an addition reaction with 40 parts by mass of glycidyl methacrylate. This is a reaction between the carboxyl group of methacrylic acid and the epoxy group of glycidyl methacrylate. The reactants were reprecipitated with purified water, filtered and dried to obtain an acrylic resin (P-3) with a weight average molecular weight (Mw) of 15,000 and an acid value of 110 (mgKOH/g).

### Example 1

175 g of carbon black (TPK1227; available from Cabot Corporation), the surface of which is modified with sulfonate groups, 57.5 g of a polyimide resin (P-1), 33.7 g of DISPERBYK-167 and 733.8 g of propylene glycol monomethyl ether acetate (hereinafter, “PGMEA”) were mixed and stirred for 20 minutes with a homo mixer (available from PRIMIX Corporation) to obtain a preliminary dispersion. The preliminary dispersion obtained was supplied to an Ultra Apex Mill (available from HIROSHIMA METAL & MACHINERY CO., LTD.) provided with a centrifugal separation separator filled with 0.30 mm-φ zirconia beads (YTZ ball; available from Neturen Co., Ltd.) at a filling ratio of 75% and dispersed for 3 hours at a rotating speed of 8 m/s to obtain a carbon black dispersion (Bk-1) with a solid content of 25% by mass and a ratio of the coloring material/the resin (mass ratio) of 70/30. In this connection, the polymeric agent DISPERBYK-167 has an amine value of mgKOH/g, no acid value and an isocyanurate ring as a pigment-adsorbing group. Moreover, the SP value of PGMEA is 8.7.

To 514.3 g of a carbon black dispersion (Bk-1), a solution prepared by dissolving 71.1 g of a polyimide resin (P-1) and 3.0 g of a PGMEA solution (10% by mass) of BYK333 (a silicone-based surfactant; available from BYK Japan KK) in 411.6 g of PGMEA was added to obtain a black resin composition 1 with the whole solid content of 20% by mass and a ratio of the coloring material/the resin component (mass ratio) of 45/55.

The black resin composition 1 obtained was applied on an alkali-free glass substrate (AN100) with a spinner (1H-DS; available from MIKASA CO., LTD.), and the coating film was subjected to pre-baking for 2 minutes at 100° C., after which the film was subjected to post-baking for 30 minutes at 230° C. to form a black film 1 with a film thickness of 1.0 μm. This black film 1 was evaluated for the following respective items. The results are shown in Table 1.

[Light Shielding Property]

Using an optical densitometer (361TVisual; available from X-Rite Inc.), the black film 1 was measured for the intensities of incident light and transmitted light respectively to calculate a light-shielding OD value from the following formula (X).

OD value=log₁₀(I₀/I) Formula (X)

I₀: Incident light intensity

I: Transmitted light intensity

[Insulation Property]

The black film 1 was measured for the surface resistivity Ω/□) using a high-resistance resistivity meter (“HIRESTA” (registered trademark) UP; available from Mitsubishi Chemical Corporation).

[Surface Roughness]

The black film 1 was measured for the surface roughness (nm) using a contact type film thickness meter (“DEKTAK” (registered trademark) 150; commercially available from ULVAC, Inc.) at a contact-needle pressure of 5 mg.

[Heat Resistance]

A portion of about 10 mg of the black film 1 was scraped to prepare a sample, and the sample was measured for the rate of loss on heating (%). More specifically, using a thermogravimetric apparatus (TGA-50; available from SHIMADZU CORPORATION), at the time when the temperature was made to reach 300° C. at a temperature increasing rate of 10° C./minute and retained at 300° C. for 30 minutes while the apparatus was purged with nitrogen gas at 50 mL/minute, the sample was measured for the mass of the sample at the point of time when the temperature reached 300° C. and the mass of the sample at the completion of the retention of 300° C. respectively, and from these values, the rate of loss on heating 1%) was calculated.

### Example 2

A carbon black dispersion (Bk-2) with a solid content of 25% by mass and a ratio of the coloring material/the resin component (mass ratio) of 70/30 was obtained in the same manner as that in Example 1 except that 56.2 g of BYK-LP N6919 was used in place of the “DISPERBYK” BYK-167 and the mass of PGMEA was set to 711.3 g. In this connection, the polymeric dispersant BYK-LP N6919 has an amine value of 72 mgKOH/g, no acid value and a tertiary amine as a pigment-adsorbing group.

A black resin composition 2 was obtained in the same manner as that in Example 1 except that the carbon black dispersion (Bk-2) was used. The black resin composition 2 obtained was used to be evaluated in the same manner as that in Example 1. The results are shown in Table 1.

### Example 3

A carbon black dispersion (Bk-3) with a solid content of 25% by mass and a ratio of the coloring material/the resin component (mass ratio) of 70/30 was obtained in the same manner as that in Example 1 except that 43.8 g of BYK-LP N21116 was used in place of the “DISPERBYK” BYK-167 and the mass of PGMEA was set to 723.7 g. The polymeric dispersant BYK-LP N21116 has an amine value of 32 mgKOH/g, no acid value and a tertiary amine and a quaternary ammonium salt as pigment-adsorbing groups.

A black resin composition 3 was obtained in the same manner as that in Example 1 except that the carbon black dispersion (Bk-3) was used. The black resin composition 3 obtained was used to be evaluated in the same manner as that in Example 1. The results are shown in Table 1.

### Example 4

A carbon black dispersion (Bk-4) with a solid content of 25% by mass and a ratio of the coloring material/the resin component (mass ratio) of 70/30 was obtained in the same manner as that in Example 1 except that 38.1 g of “DISPERBYK” BYK-2001 was used in place of the “DISPERBYK” BYK-167 and the mass of PGMEA was set to 729.4 g. In this connection, the polymeric dispersant “DISPERBYK” BYK-2001 has an amine value of 29 mgKOH/g, an acid value of 19 mg/KOH and a quaternary ammonium salt as a pigment-adsorbing group.

A black resin composition 4 was obtained in the same manner as that in Example 1 except that the carbon black dispersion (Bk-4) was used. The black resin composition 4 obtained was used to be evaluated in the same manner as that in Example 1. The results are shown in Table 1.

### Example 5

An organic black dispersion (Bk-5) with a solid content of 25% by mass and a ratio of the coloring material/the resin component (mass ratio) of 60/40 was obtained in the same manner as that in Example 1 except that 150.0 g of the organic black “Irgaphor” Black S0100CF (available from BASF) was mixed with 75.0 g of a polyimide resin (P-1), 25.0 g of “SOLSPERSE” 20000 (available from The Lubrizol Corporation) and 750 g of 3-methoxybutyl acetate (hereinafter, “MBA”). In this connection, the polymeric dispersant “SOLSPERSE” 20000 has an amine value of 29 mgKOH/g, no acid value and a tertiary amine as a pigment-adsorbing group. Moreover, the SP value of MBA is 8.7.

In 400 g of an organic black dispersion (Bk-5), 100 g of a polyimide resin (P-1), 3.0 g of a PGMEA solution (10% by mass) of BYK333 (a silicone-based surfactant; available from BYK Japan KK) and 497 g of PGMEA were dissolved to obtain a black resin composition 5 with the whole solid content of 20% by mass and a ratio of the coloring material/the resin component (mass ratio) of 30/70. The black resin composition 5 obtained was used to be evaluated in the same manner as that in Example 1. The results are shown in Table 1.

### Comparative Example 1

Although a carbon black dispersion was attempted to be obtained in the same manner as that in Example 1 except that the mass of a polyimide resin (P-1) was set to 91.2 g and a polymeric dispersant (“DISPERBYK”-167) was not added, a carbon black dispersion failed to be obtained because particles of carbon black were agglomerated during the dispersing operation using an Ultra Apex Mill and the viscosity was excessively increased.

### Comparative Example 2

A carbon black dispersion (Bk-7) with a solid content of 25% by mass and a ratio of the coloring material/the resin component (mass ratio) of 70/30 was obtained in the same manner as that in Example 1 except that 375 g of a polyimide precursor (P-2) solution was used in place of the polyimide resin (P-1) and 450 g of NMP was used in place of the PGMEA, respectively. In this connection, the SP value of NMP is 11.0.

To 257.1 g of a carbon black dispersion (Bk-4), 178.6 g of a polyimide precursor (P-2) solution, 563.3 g of NMP and 1 g of LC951 (available from Kusumoto Chemicals, Ltd.) which is a surfactant were added to obtain a black resin composition 7 with the whole solid content of 10% by mass and a ratio of the pigment/the resin component (mass ratio) of 45/55.

The black resin composition 7 obtained was used to be evaluated in the same manner as that in Example 1. The results are shown in Table 1.

### Comparative Example 3

Although a carbon black dispersion was attempted to be obtained in the same manner as that in Example 1 except that 375 g of a polyimide precursor (P-2) solution was used in place of the polyimide resin (P-1), the mass of PGMEA was set to 450 g, and furthermore, a polymeric dispersant (“DISPERBYK”-167) was not added, a carbon black dispersion failed to be obtained because the resin component was precipitated during the stirring operation with a homo mixer.

### Comparative Example 4

A carbon black dispersion (Bk-8) with a solid content of 25% by mass and a ratio of the coloring material/the resin component (mass ratio) of 70/30 was obtained in the same manner as that in Example 1 except that 57.5 g of an acrylic polymer (P-3) was used in place of the polyimide resin (P-1).

A black resin composition 8 was obtained in the same manner as that in Example 1 except that the carbon black dispersion (Bk-8) was used. The black resin composition 8 obtained was used to be evaluated in the same manner as that in Example 1. The results are shown in Table 1.

### Comparative Example 5

A carbon black dispersion (Bk-9) with a solid content of 25% by mass and a ratio of the coloring material/the resin component (mass ratio) of 70/30 was obtained in the same manner as that in Example 1 except that 101.8 g of a PGMEA solution (P-4) of a polycondensate of an epoxy acrylate having a fluorene skeleton with an acid anhydride (solid content 56.5% by mass; V259ME; available from NIPPON STEEL & SUMIKIN CHEMICAL CO., LTD.) was used in place of the polyimide resin (P-1) and the mass of PGMEA was set to 689.5 g.

A black resin composition 9 was obtained in the same manner as that in Example 1 except that the carbon black dispersion (Bk-9) was used. The black resin composition 9 obtained was used to be evaluated in the same manner as that in Example 1. The results are shown in Table 1.

### Example 6

To 499.5 g of a carbon black dispersion (Bk-1), a solution prepared by dissolving 19.2 g of a polyimide resin (P-1), 47.9 g of dipentaerythritol hexaacrylate, 5.8 g of “ADEKA CRUISE” NCI-831 (available from ADEKA CORPORATION) which is a photo-radical polymerization initiator, 2.0 of KBM503 (available from Shin-Etsu Chemical Co., Ltd.) which is an adhesion improving agent, and 2.0 g of BYK333 in 425.4 g of PGMEA was added to obtain a photosensitive black resin composition 10 with a solid content of 20% by mass and a ratio of the pigment/the resin (mass ratio) of 45/55.

The photosensitive black resin composition 10 obtained was applied on an alkali-free glass substrate with a spinner, and the coating film was pre-dried for 2 minutes at 100° C., after which the film was subjected to exposure (200 mJ/cm²) through a photomask using the mask aligner PEM-6M (available from Union Optical Co., LTD.). This film was subjected to development using a 0.045% by mass aqueous KOH solution, subsequently, washed with pure water, and subjected to post-baking for 30 minutes at 230° C. to form a black film 10 with a film thickness of 1.0 μm. This black film 10 was evaluated in the same manner as that in Example 1. The results are shown in Table 1.

A black film formed by curing a melanotic composition described in EXAMPLES and 10 is excellent in the light shielding property, insulation property and surface smoothness (surface roughness), and it has been found that the composition is extremely satisfactory in the dispersion state of pigments. Furthermore, the rate of loss on heating (%) is very low, the outgassed component from a coating film is extremely small in amount, and it has been found that a colored film excellent in heat resistance is formed.

TABLE 1

| | | Black resin composition | | | | valuation results of colored resin fil | | | |
|---|---|---|---|---|---|---|---|---|---|
| | Black | Alkali-soluble | Coloring | Polymeric | Organic | Light- | Surface | Surface | Loss |
| | resin | resin | material | dispersant | solvent | shielding | resistance | roughness | on |
| | composition | (A) | (B) | (C) | (D) | OD value | [Ω/□] | [Å] | heating |
| Example 1 | BK-1 | P-1 | TPK12227 | DISPERBYK- | PGMEA | 3.0 | >10\hat{ }15 | 15 | 0.5% |
| | | | | 167 | | | | | |
| Example 2 | BK-2 | P-1 | TPK12227 | BKK-LP | PGMEA | 3.0 | >10\hat{ }15 | 10 | 0.3% |
| | | | | N6919 | | | | | |
| Example 3 | BK-3 | P-1 | TPK12227 | BKK-LP | PGMEA | 3.0 | >10\hat{ }15 | 15 | 0.3% |
| | | | | N21116 | | | | | |
| Example 4 | BK-4 | P-1 | TPK12227 | DISPERBYK- | PGMEA | 2.7 | >10\hat{ }15 | 40 | 0.3% |
| | | | | 2001 | | | | | |
| Example 5 | BK-5 | P-1 | Irgaphor | SOLSPERSE | MBA | 1.6 | >10\hat{ }15 | 30 | 0.3% |
| | | | Black | 20000 | | | | | |
| | | | S0100CF | | | | | | |
| Comparative | BK-6 | P-1 | TPK12227 | — | PGMEA | — | — | — | — |
| Example 1 | | | | | | | | | |
| Comparative | BK-7 | P-2 | TPK12227 | DISPERBYK- | NMP | 2.7 | 10\hat{ }6 | 60 | 0.1% |
| Example 2 | | | | 167 | | | | | |
| Comparative | BK-8 | P-2 | TPK12227 | DISPERBYK- | PGMEA | — | — | — | — |
| Example 3 | | | | 167 | | | | | |
| Comparative | BK-9 | P-3 | TPK12227 | DISPERBYK- | PGMEA | 3.0 | >10\hat{ }15 | 20 | 3.5% |
| Example 4 | | | | 167 | | | | | |
| Comparative | BK-10 | P-4 | TPK12227 | DISPERBYK- | PGMEA | 3.0 | >10\hat{ }15 | 20 | 2.1% |
| Example 5 | | | | 167 | | | | | |
| Comparative | BK-11 | P-1 | TPK12227 | DISPERBYK- | PGMEA | 3.2 | >10\hat{ }15 | 15 | 0.6% |
| Example 6 | | | | 167 | | | | | |

The colored resin composition of the present invention can be suitably utilized for a colored film of a decorative substrate with which a touch panel is provided and the formation of a colored insulating layer in an organic EL display device.

1. A colored resin composition comprising:
(A) an alkali-soluble polyimide resin containing a structural unit represented by the following general formula (1),
(B) a coloring material,
(C) a polymeric dispersant, and
(D) an organic solvent; 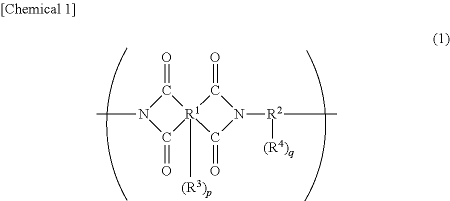
wherein:
R¹ represents a 4- to 10-valent organic group,
R² represents a 2- to 8-valent organic group,
R³ and R⁴ independently represent a phenolic hydroxyl group, a sulfonic acid group or a thiol group,
p and q independently represent an integer of 0 to 6, and the sum of p and q is greater than or equal to 1;
(B) a coloring material,
(C) a polymeric dispersant, and
(D) an organic solvent;
wherein:
a mass ratio of the (B) coloring material to a resin component containing the (A) alkali-soluble polyimide resin and the (C) polymeric dispersant is 90/10 to 20/80,
the (C) polymeric dispersant includes a main chain selected from polyamine, polyether, polyester, polyurethane, or poly(meth)acrylate, and a functional group with a polarity which is selected from an amine, a carboxylic acid, a phosphoric acid, an amine salt, a carboxylate, or phosphate as a side chain,
the (D) organic solvent contains 70 to 100% by mass or more of an acetate-based solvent.

2. The colored resin composition according to claim 1, wherein the (C) polymeric dispersant has no acid value and has an amine value.

3. The colored resin composition according to claim 1, wherein the (C) polymeric dispersant has a tertiary amino group or a nitrogen-containing heterocyclic basic functional group.

4. The colored resin composition according to claim 1, wherein the (D) organic solvent is composed mainly of an acetate-based solvent.

5. The colored resin composition according to claim 1, wherein the (B) coloring material is composed of an organic pigment and/or an inorganic pigment.

6. A colored film being composed of a cured product of the colored resin composition according to claim 1.

7. A decorative substrate being provided with the colored film according to claim 6.

8. A touch panel being provided with the decorative substrate according to claim 7.

9. An organic EL display device having the colored film according to claim 6 on at least one layer of a flattening layer on a driving circuit and an insulating layer on a first electrode.
